(19) United States
(12) Patent Application Publication
(10) Pub. No.: US 2015/0129779 A1
(43) Pub. Date: May 14, 2015

(54) DRAWING APPARATUS, AND METHOD OF MANUFACTURING ARTICLE

(71) Applicant: CANON KABUSHIKI KAISHA, Tokyo (JP)

(72) Inventors: Tomoyuki Morita, Utsunomiya-shi (JP); Kazuya Kikuchi, Utsunomiya-shi (JP)

(21) Appl. No.: 14/528,192

(22) Filed: Oct. 30, 2014

(30) Foreign Application Priority Data
Nov. 11, 2013 (JP) 2013-233454

(51) Int. Cl. H01J 37/20; H01J 37/30; G21K 5/10

(52) U.S. Cl. CPC H01J 37/20; G21K 5/10; H01J 37/3007; H01J 2237/303
USPC 250/453.11

(57) ABSTRACT

The present invention provides a drawing apparatus which performs drawing on a substrate with a charged particle beam, the apparatus comprising a deflector configured to scan the charged particle beam on the substrate, a stage configured to hold the substrate and be movable, and a controller configured to control main-scan by the deflector and sub-scan by movement of the stage, wherein the controller is configured to control a width of the main-scan based on a width of a target drawing region on the substrate in a direction of the main-scan.

### BACKGROUND OF THE INVENTION

1. Field of the Invention

The present invention relates to a drawing apparatus, and a method of manufacturing an article.

2. Description of the Related Art

Along with micropatterning and high integration of circuit patterns in semiconductor integrated circuits, attention is paid to a drawing apparatus which draws a pattern on a substrate by using a charged particle beam (electron beam), as described in International Publication No. 2009-147202. In the drawing apparatus, if a target drawing region on a substrate to undergo drawing with a charged particle beam is displaced from an original position on the substrate, it may become difficult to draw a pattern at high overlay precision. Hence, Japanese Patent Nos. 3940310 and 4563756 have proposed drawing apparatuses which perform drawing by increasing the deflection width by which a charged particle beam is deflected so that the positional displacement of the target drawing region is compensated for. Note that the increased deflection width should not be always used in terms of the throughput of the drawing apparatus.

In the drawing apparatuses disclosed in Japanese Patent Nos. 3940310 and 4563756, the deflection width of a charged particle beam is merely increased by the displacement amount of the center coordinates of a target drawing region formed on a substrate. That is, Japanese Patent Nos. 3940310 and 4563756 do not describe a technique of increasing the deflection width of a charged particle beam in accordance with the length of a target drawing region in a direction in which the charged particle beam is deflected.

### SUMMARY OF THE INVENTION

The present invention provides, for example, a drawing apparatus advantageous in terms of overlay precision and throughput.

According to one aspect of the present invention, there is provided a drawing apparatus which performs drawing on a substrate with a charged particle beam, the apparatus comprising: a deflector configured to scan the charged particle beam on the substrate; a stage configured to hold the substrate and be movable; and a controller configured to control main-scan by the deflector and sub-scan by movement of the stage, wherein the controller is configured to control a width of the main-scan based on a width of a target drawing region on the substrate in a direction of the main-scan.

Further features of the present invention will become apparent from the following description of exemplary embodiments with reference to the attached drawings.

### BRIEF DESCRIPTION OF THE DRAWINGS

FIG. 1 is a view showing a drawing apparatus according to the present invention;

FIG. 2 is a view showing a pattern to be drawn on a substrate;

FIG. 3A is a view for explaining a range in which drawing becomes possible by deflecting a charged particle beam by a deflector array;

FIG. 3B is a view for explaining a range in which drawing becomes possible by deflecting a charged particle beam by a deflector array, and moving a substrate;

FIG. 4 is a view showing the positional relationship between each objective lens and a stripe region;

FIG. 5 is a view showing the array of a plurality of shot regions formed on a substrate;

FIG. 6 is a view showing the relationship between a stripe region and a shot region;

FIG. 7A is a view for explaining a method of performing drawing in a target drawing region;

FIG. 7B is a view for explaining the method of performing drawing in a target drawing region;

FIG. 7C is a view for explaining the method of performing drawing in a target drawing region;

FIG. 7D is a view for explaining the method of performing drawing in a target drawing region;

FIG. 7E is a view for explaining the method of performing drawing in a target drawing region;

FIG. 8A is a view for explaining a method of determining the deflection width of a charged particle beam for each shot region array;

FIG. 8B is a view for explaining the method of determining the deflection width of a charged particle beam for each shot region array;

FIG. 9A is a view for explaining a method of determining the deflection width of a charged particle beam for each shot region;

FIG. 9B is a view for explaining the method of determining the deflection width of a charged particle beam for each shot region; and

FIG. 9C is a view for explaining the method of determining the deflection width of a charged particle beam for each shot region.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

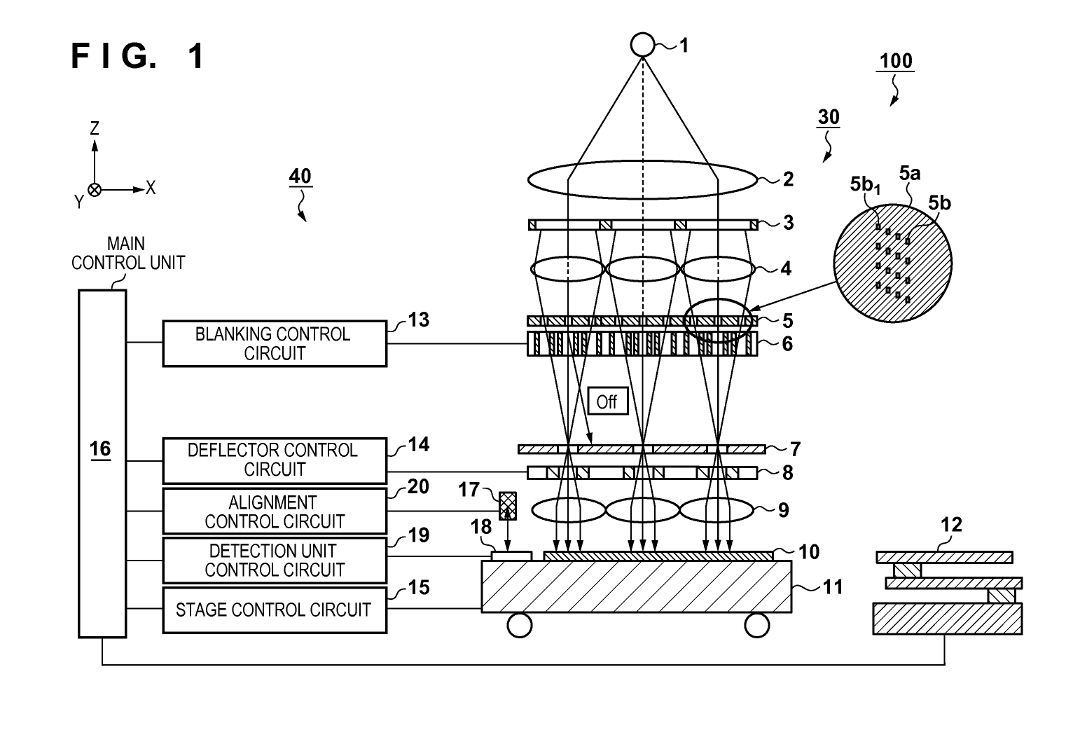

A drawing apparatus 100 according to the present invention will be described with reference to FIG. 1. The drawing apparatus 100 can be constituted by a drawing unit 30 which draws a pattern by irradiating a substrate 10 (for example, wafer) with a charged particle beam, and a control unit 40 (a controller) which controls each unit of the drawing unit 30. The drawing unit 30 includes, for example, a charged particle source 1, collimator lens 2, first aperture array 3, condenser lens array 4, second aperture array 5, blanker array 6, blanking aperture 7, deflector array 8, and objective lens array 9. The drawing unit 30 includes a stage 11 (X-Y stage) configured to be movable while holding the substrate 10.

The charged particle source 1 emits a charged particle beam (electron beam). As the charged particle source 1, for example, a so-called thermoelectron emission electron source including a thermoelectron emission material such as LaB₆ or BaO/W (dispenser cathode) can be used. As the collimator lens 2, for example, an electrostatic lens which condenses a charged particle beam by an electric field is used. The collimator lens 2 collimates a charged particle beam emitted by the charged particle source 1 into a parallel beam, and makes the parallel beam enter the first aperture array 3. Although the drawing apparatus 100 draws a pattern on a substrate with a plurality of electron beams, it may use a charged particle beam such as an ion beam, other than an electron beam. The drawing apparatus 100 can be generalized as a drawing apparatus which draws a pattern on a substrate with a plurality of charged particle beams.

The first aperture array 3 has two-dimensionally arrayed openings, and divides a charged particle beam incident as a parallel beam into a plurality of charged particle beams. The charged particle beams divided by the first aperture array 3 pass through the condenser lens array 4 and irradiate the second aperture array 5. The second aperture array includes a plurality of sub-arrays 5a in each of which a plurality of openings 5b for defining (determining) the shape of a charged particle beam are formed. Each sub-array 5a is arranged in correspondence with each charged particle beam divided by the first aperture array 3. The sub-array 5a further divides each charged particle beam, generating a plurality of charged particle beams. The sub-array 5a shown in FIG. 1 has, for example, 16 (4×4) openings 5b. With this structure, the sub-array 5a can further divide each charged particle beam, which has been divided by the first aperture array 3, into 16 (4×4) beams.

A plurality of charged particle beams divided by the second aperture array 5 enter the blanker array 6 including a plurality of blankers for individually deflecting a plurality of charged particle beams. The blanker is constituted by two facing electrodes. By applying a voltage between the two electrodes, the blanker can generate an electric field to deflect a charged particle beam. A charged particle beam deflected by the blanker array 6 is blocked by the blanking aperture 7 arranged on the subsequent stage of the blanker array 6, and does not reach the substrate. In contrast, a charged particle beam not deflected by the blanker array 6 passes through an opening formed in the blanking aperture 7 and reaches the substrate. That is, the blanker array 6 switches between irradiation and non-irradiation of the substrate 10 with a charged particle beam. A charged particle beam having passed through the blanking aperture 7 enters the deflector array 8 which deflects a charged particle beam to scan it on the substrate. The deflector array 8 includes a plurality of deflectors. Parallel to deflection of each charged particle beam by the blanker array 6, each deflector deflects at once a plurality of charged particle beams in, for example, the X direction (first direction). Accordingly, a plurality of charged particle beams having passed through the objective lens array 9 can be scanned on the substrate. The deflector array 8 shown in FIG. 1 is constituted by a plurality of deflectors so that one deflector corresponds to one sub-array 5a. However, the deflector array 8 is not limited to this, and may be constituted so that one deflector corresponds to the plurality of sub-arrays 5a.

In the drawing apparatus 100, a plane on which the sub-arrays 5a are arrayed serves as the object plane, and the upper surface of the substrate 10 serves as an image plane. A charged particle beam emitted by the charged particle source 1 forms an image on the blanking aperture 7 through the collimator lens 2 and one condenser lens of the condenser lens array 4. The size of an image to be formed is set to be larger than the opening of the blanking aperture 7. Therefore, the semi-angle (half-angle) of a charged particle beam to irradiate the substrate 10 is defined by the opening of the blanking aperture 7. The opening of the blanking aperture 7 is arranged at the front focal position of a corresponding objective lens OL. The principal rays of a plurality of charged particle beams emerging from the plurality of openings 5b of the sub-array 5a almost perpendicularly enter the substrate. Even if the upper surface of the substrate is displaced vertically, the displacement of a charged particle beam on the horizontal plane is small.

The stage 11 (X-Y stage) is configured to be movable within the X-Y plane (horizontal plane) perpendicular to the optical axis, while holding the substrate 10. The stage 11 includes a chuck mechanism (not shown) such as an electrostatic chuck for holding (chucking) the substrate 10. A detection unit 18 which includes an opening pattern which a charged particle beam enters, and detects the position of a charged particle beam, and an alignment measurement unit 17 (a measurement device) which measures the shape of each shot region SH formed on the substrate 10 are arranged on the stage 11. The detection unit 18 includes, for example, a Faraday cup which detects the entrance of a charged particle beam. The detection unit 18 can detect the position of a charged particle beam from the position of the stage 11 upon detecting the entrance of the charged particle beam. The position of the stage 11 can be measured by, for example, a measurement device (not shown) including a laser interferometer and encoder. The alignment measurement unit 17 can measure the shape of each shot region SH by detecting the positions of a plurality of alignment marks respectively formed at four corners of the shot region SH. A transport mechanism 12 transports the substrate 10, and transfers the substrate 10 between the transport mechanism 12 and the stage 11.

The control unit 40 can include, for example, a blanking control circuit 13, deflector control circuit 14, stage control circuit 15, alignment control circuit 20, detection unit control circuit 19, and controller 16. The blanking control circuit 13 individually controls a plurality of blankers constituting the blanker array 6 based on drawing data supplied from the controller 16. The deflector control circuit 14 controls a plurality of deflectors constituting the deflector array 8 based on a common signal supplied from the controller 16. The stage control circuit 15 controls positioning of the stage in cooperation with the measurement device (not shown) for measuring the position of the stage 11. The measurement device can include, for example, a laser interferometer and encoder. The alignment control circuit 20 controls the alignment measurement unit 17 to measure the shape of each shot region SH. The detection unit control circuit 19 controls the detection unit 18 to detect the position of a charged particle beam. The controller 16 includes a CPU and memory, controls the plurality of control circuits 13 to 15, 19, and 20 described above, and executively controls the drawing apparatus 100. The control unit 40 of the drawing apparatus 100 is constituted by the plurality of control circuits 13 to 15, 19, and 20, and the controller 16 in FIG. 1. However, this is merely an example, and the control unit 40 can be appropriately changed.

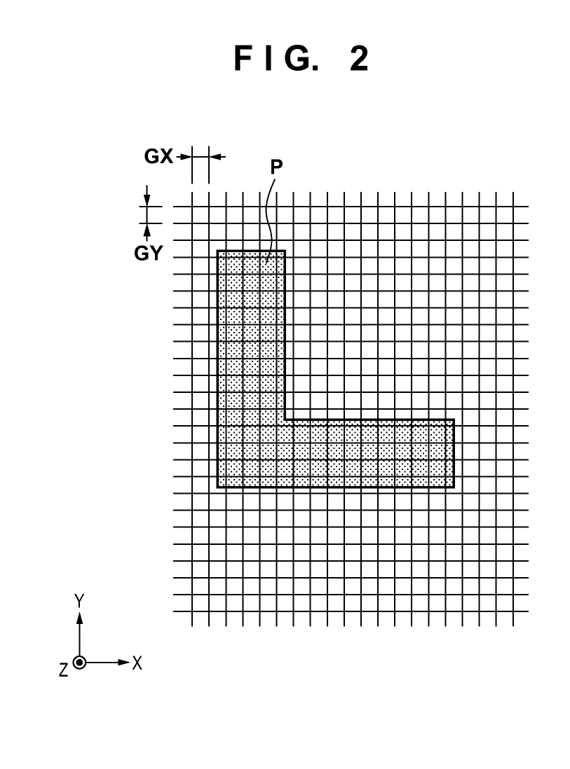

A raster scan drawing method for the drawing apparatus 100 having this arrangement will be explained with reference to FIG. 2. FIG. 2 is a view showing a pattern to be drawn on the substrate 10. While a charged particle beam is scanned on scan grids on a substrate that are determined by deflection by the deflector array 8 and the position of the stage 11, the blanker array 6 controls irradiation and non-irradiation of the charged particle beam on the substrate in accordance with a drawing pattern P. The scan grid is a grid defined by a pitch GX in the X direction and a pitch GY in the Y direction. Irradiation or non-irradiation of a charged particle beam is assigned to an intersection point (grid point) between a vertical line and a horizontal line shown in FIG. 2. The control unit 40 controls the stage 11 to continuously move (sub-scan) the substrate 10 in the Y direction (second direction), while controlling the deflector array 8 to deflect each charged particle beam and scan (main-scan) it in the X direction (first direction) on the substrate. Parallel to the deflection of each charged particle beam in the X direction by the deflector array 8, the control unit 40 controls the blanker array 6 to control irradiation and non-irradiation of each charged particle beam for each grid point defined by the pitch GX. In the embodiment, the first and second directions are the X and Y directions perpendicular to each other on a plane parallel to the substrate surface. However, the first and second directions suffice to be different directions on a plane parallel to the substrate surface. In the embodiment, the first direction (X direction) serves as the main-scan direction, and the second direction (Y direction) serves as the sub-scan direction.

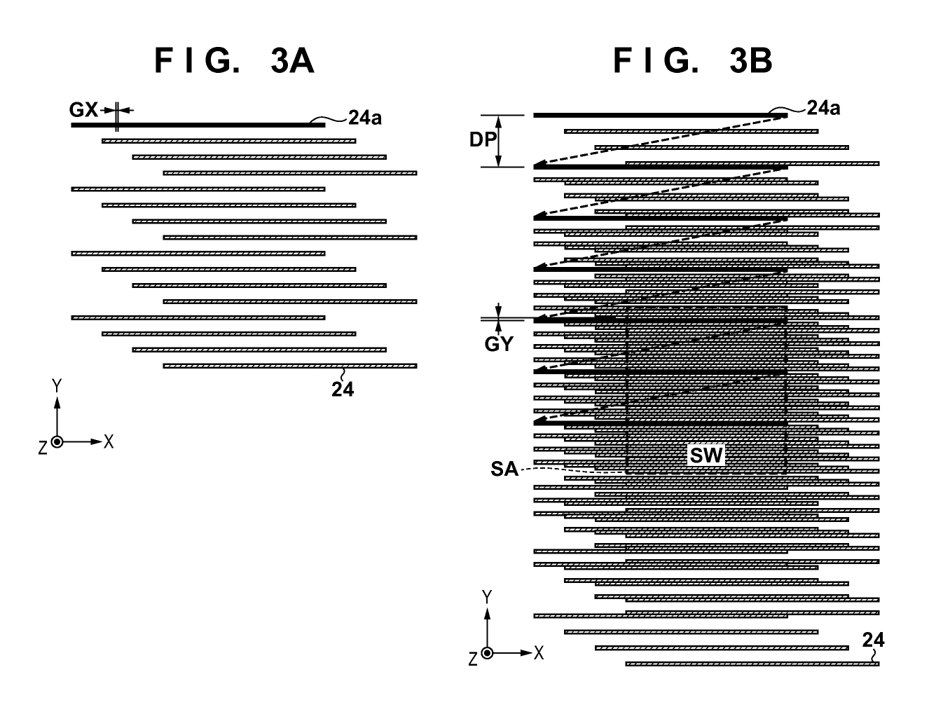

A range on a substrate in which a plurality of charged particle beams divided by one sub-array 5a can perform drawing by deflecting (main-scanning) charged particle beams by the deflector array 8, and moving (sub-scanning) the substrate 10 by the stage 11 will be explained with reference to FIGS. 3A and 3B. FIG. 3A is a view showing a region 24 on the substrate that is drawn by each charged particle beam when the deflector array 8 deflects once in the X direction a plurality of charged particle beams divided by one sub-array. FIG. 3B is a view showing a range (stripe region SA) in which a plurality of charged particle beams divided by one sub-array can perform drawing by deflecting the charged particle beams by the deflector array 8, and moving the substrate 10 by the stage 11. In FIGS. 3A and 3B, each charged particle beam always irradiates the substrate 10. In practice, however, the blanker array 6 controls irradiation and non-irradiation of each charged particle beam for each grid point defined by the pitch GX, as described above.

In FIG. 3B, a filled region 24a is the region 24 which is drawn by a charged particle beam which has passed through an opening 5b₁ formed in the sub-array 5a and has been deflected by the deflector array 8. The charged particle beam having passed through the opening 5b₁ draws the top region 24a, and then sequentially draws the regions 24a via flyback (distance DP) in the −X direction and movement of the stage 11 in the −Y direction, as indicated by arrows of broken lines. At this time, charged particle beams having passed through the openings 5b other than the opening 5b₁ also perform drawing on the substrate 10 similarly to the charged particle beam having passed through the opening 5b₁. As a result, the stripe region SA having a stripe width SW can be filled with the regions 24 drawn by respective charged particle beams, as represented by broken lines in FIGS. 3A and 3B. That is, the drawing apparatus 100 can draw the stripe region SA by repeating continuous movement of the stage 11 and deflection of a charged particle beam by the deflector array 8. The stripe region SA is a region on the substrate in which drawing is possible by a plurality of charged particle beams having passed through one sub-array 5a.

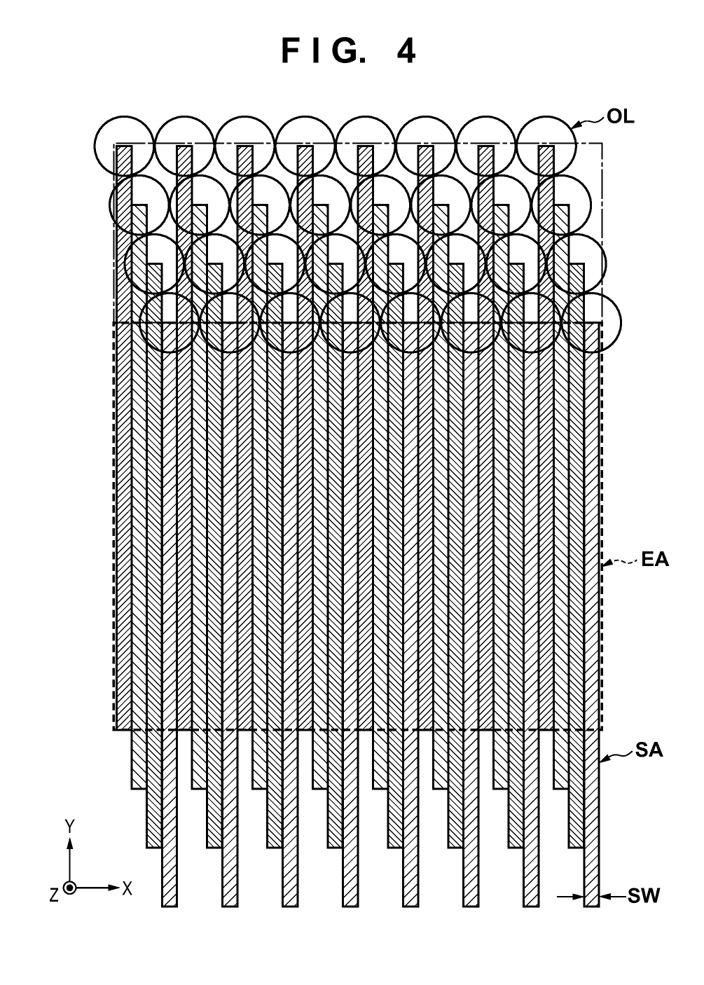

FIG. 4 is a view showing the positional relationship between each objective lens OL (or each sub-array 5a) of the objective lens array 9, and the stripe region SA. As described above, one stripe region SA is a region on the substrate in which drawing is possible by a plurality of charged particle beams divided by one sub-array. A plurality of charged particle beams divided by one sub-array 5a pass through one objective lens OL in the objective lens array 9.

For example, as shown in FIG. 4, the objective lens array 9 is constituted so that a plurality of arrays each having a plurality of objective lenses OL arrayed at a pitch of 144 μm in the X direction are arranged in the Y direction with a displacement of 2 μm, which is the stripe width SW, in the X direction. By constituting the objective lens array 9 in this manner, the plurality of stripe regions SA can be arranged without any gap. The objective lens array 9 is constituted by 4×8 objective lenses OL in FIG. 4, but can be configured by as many as 72×180 objective lenses OL in practice. With this configuration, drawing can be performed in a drawing region EA on the substrate by continuously moving (sub-scanning) the stage 11 in one direction along the Y direction.

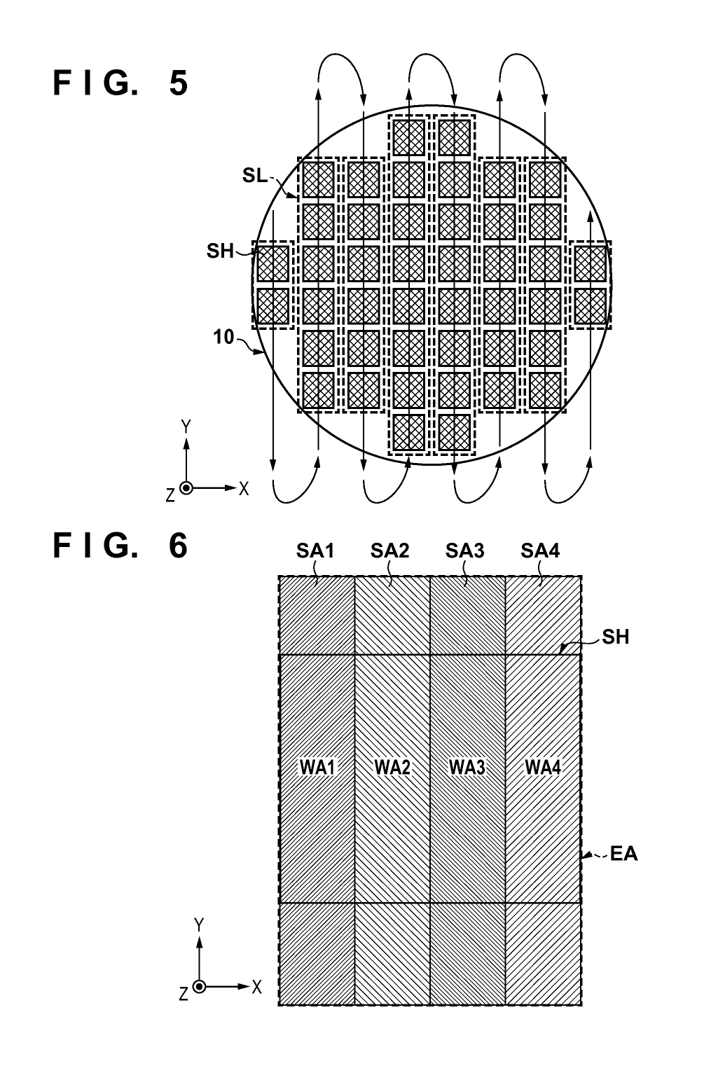

Next, a method of performing drawing in a plurality of shot regions SH two-dimensionally arrayed on a substrate will be explained with reference to FIG. 5. The shot region SH is a drawing unit, and drawing data can be processed and modified for this unit. The size of the shot region SH may match the size (26 mm×33 mm) of the shot region of an optical exposure apparatus, for the process in mix-and-match with the optical exposure apparatus.

For example, the width (length in the X direction) of the drawing region EA is set to be larger than the width of one shot region SH in the X direction. By continuously moving the substrate 10 in the Y direction by the stage 11, drawing can be performed for each shot region array SL including at least two shot regions SH arrayed in the Y direction. After performing drawing in a plurality of shot regions included in one shot region array SL, the drawing apparatus 100 moves the substrate 10 in the X direction by the stage 11, and performs drawing in a plurality of shot regions included in the adjacent shot region array SL. By repeating this processing, the drawing apparatus 100 can perform drawing in an order indicated by arrows in FIG. 5 in the plurality of shot regions SH formed on the substrate 10. If the plurality of shot regions SH arranged on the substrate have the same shape, the same drawing data can be repetitively used. This can shorten the time for processing drawing data, and is advantageous in productivity. A case in which the width of the drawing region EA is larger than that of the shot region in the X direction has been described with reference to FIG. 5. However, even when the width of the drawing region EA is smaller than that of the shot region SH, drawing in the shot region SH can be performed in the drawing region EA. For example, the shot region SH is divided by the plurality of drawing regions EA to perform drawing.

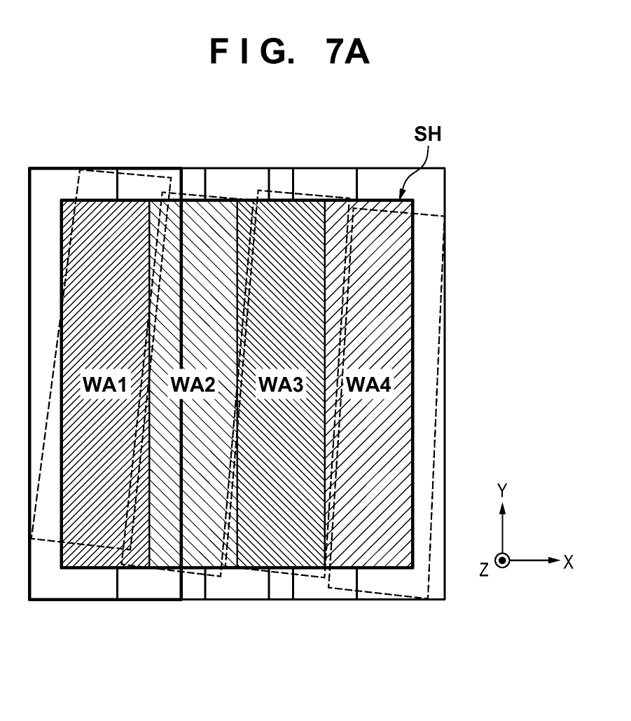

FIG. 6 is a view showing the relationship between the stripe region SA constituting the drawing region EA, and the shot region SH. In FIG. 4, the drawing region EA is constituted by 4×8 stripe regions SA. In FIG. 6, the drawing region EA is constituted by four stripe regions SA for descriptive convenience. The four stripe regions SA are represented by stripe regions SA1 to SA4, respectively. The shot region SH is divided by the stripe regions SA1 to SA4, and the respective portions of the divided shot region are represented by target drawing regions WA1 to WA4, respectively. The target drawing regions WA1 to WA4 are target regions in which drawing is performed by a plurality of charged particle beams having passed through each sub-array 5a (each objective lens OL). The target drawing regions WA1 to WA4 are parts of the shot region. The subsequent description also assumes that the drawing region EA is constituted by the four stripe regions SA1 to SA4, and the shot region SH is constituted by the four target drawing regions WA1 to WA4.

<Correction by Addition of Correction Region>

When performing drawing in the shot region SH, it sometimes becomes difficult to draw a pattern in the shot region SH at high precision owing to an error arising from the distortion (deformation) of the shot region SH formed on the substrate 10, or an error arising from the displacement of the irradiation position of a charged particle beam. To solve this, the drawing apparatus 100 may acquire information indicating the distortion of a shot region (information regarding the size of a shot region in the main-scan direction) and information indicating the displacement of the irradiation position of a charged particle beam, and controls drawing in the shot region SH based on these pieces of information. The error arising from the displacement of the irradiation position of a charged particle beam is an error generated from the displacement of the irradiation position of a charged particle beam on the substrate from a target position.

The information indicating the distortion of the shot region SH can include a measurement result of measuring the shape (including the position) of the shot region SH by the alignment measurement unit 17. The information indicating the distortion of the shot region SH can also include information indicating the measurement error of the alignment measurement unit 17, and information indicating the thermal deformation of the shot region SH that is caused by irradiating the substrate 10 with a charged particle beam. The measurement error of the alignment measurement unit 17 can be acquired by measuring again, by an alignment measurement device such as an overlay inspection apparatus outside the drawing apparatus 100, the shape of the shot region SH measured by the alignment measurement unit 17. The thermal deformation of the shot region SH can be acquired by experiment, simulation, or the like. Assume that the correction amount of the shot region based on information indicating the distortion of the shot region SH is given by equation (1). Xs and Ys are arbitrary drawing coordinates in a shot coordinate system having the center of the shot region SH as the origin, dXs and dYs are the correction amounts of the shot region SH at respective drawing coordinates, and Ax, Bx, Cx, Dx, Ay, By, Cy, and Dy are the correction coefficients of the position and shape of the shot region SH.

$$( \begin{matrix}dXs \\ dYs\end{matrix} ) = ( \begin{matrix}Ax & Bx & Cx & Dx \\ Ay & By & Cy & Dy\end{matrix} ) \cdot [ \begin{matrix}Xs \\ Ys \\ Xs \cdot Ys \\ 1\end{matrix} ] \qquad ( 1 )$$

Similarly, the displacement of the irradiation position of a charged particle beam arising from the error or contamination of an electron lens or deflector is generated mainly for each sub-array 5a (or objective lens OL). Information indicating the displacement of the irradiation position of a charged particle beam is detected in advance by the detection unit 18 as the average amount of a plurality of charged particle beams divided by the sub-array 5a. Assume that the correction amount of the shot region SH based on this information is given by equation (2). Xb and Yb are drawing coordinates obtained by replacing the shot coordinate system with a beam deflection coordinate system having the deflection center of each sub-array 5a as the origin, dXn and dYn are the correction amounts of the shot region SH at respective drawing coordinates, and Axn, Bxn, Cxn, Dxn, Ayn, Byn, Cyn, and Dyn are the correction coefficients of the displacement of the irradiation position of a charged particle beam. A numeral for discriminating each sub-array 5a (or objective lens OL) is substituted into n.

$$( \begin{matrix}dXn \\ dYn\end{matrix} ) = ( \begin{matrix}Axn & Bxn & Cxn & Dxn \\ Ayn & Byn & Cyn & Dyn\end{matrix} ) \cdot [ \begin{matrix}Xb \\ Yb \\ Xb \cdot Yb \\ 1\end{matrix} ] \qquad ( 2 )$$

Drawing coordinates (Xs′, Ys′) after correcting an error arising from the distortion of the shot region SH that is represented by equation (1), and an error arising from the displacement of the irradiation position of a charged particle beam that is represented by equation (2) are given by:

$$( \begin{matrix}{Xs}^{′} \\ {Ys}^{′}\end{matrix} ) = ( \begin{matrix}Xs + dXs + dXn \\ Ys + dYs + dYn\end{matrix} ) \qquad ( 3 )$$

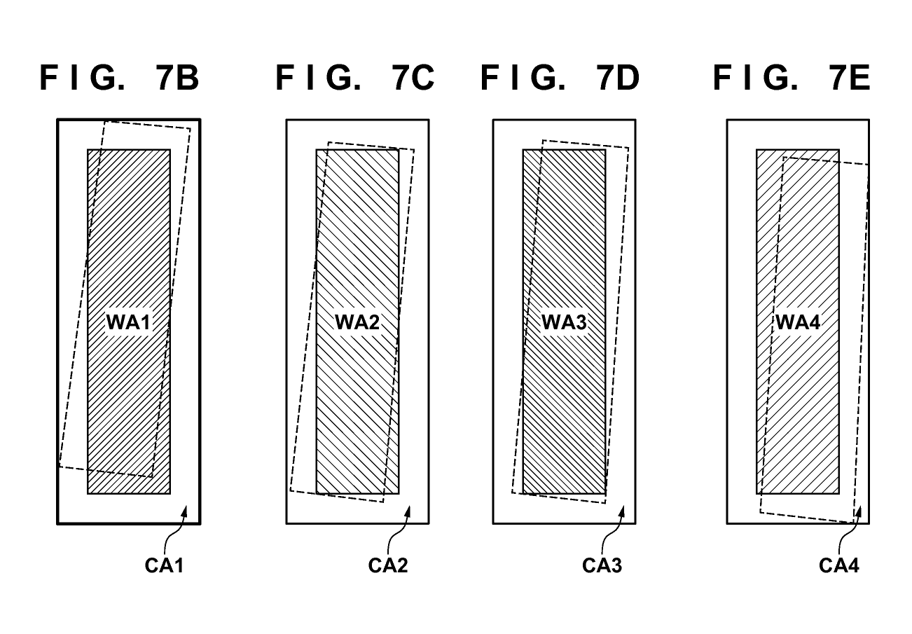

Next, a method of performing drawing in the target drawing regions WA1 to WA4 by correcting an error arising from the distortion of the shot region SH, and an error arising from the displacement of the irradiation position of a charged particle beam will be explained with reference to FIGS. 7A to 7E. FIG. 7A is a view showing a state in which the target drawing regions WA1 to WA4 are arranged according to design data. FIGS. 7B to 7E are views individually showing the target drawing regions WA1 to WA4 in FIG. 7A for descriptive convenience. Assume that drawing data of the target drawing regions WA1 to WA4 constituting the shot region SH represent regions WA1′ to WA4′ indicated by broken lines in FIGS. 7A to 7E as a result of performing the correction based on the above-described equation (3). That is, an error arising from the distortion of the shot region SH, and an error arising from the displacement of the irradiation position of a charged particle beam can be corrected by performing drawing based on drawing data (regions WA1′ to WA4′ indicated by the broken lines in FIGS. 7A to 7E) corrected according to equation (3). To perform drawing based on drawing data corrected according to equation (3), correction regions CA1 to CA4 are added to the respective target drawing regions WA1 to WA4, as shown in FIGS. 7A to 7E. For example, the correction regions CA1 to CA4 are added by extending the stripe width SW in the X direction so that the adjacent stripe regions SA overlap each other, and by simply extending the region in the Y direction. In FIGS. 7A to 7E, a thick line indicates a region obtained by adding the correction region CA1 to the target drawing region WA1, in order to facilitate understanding.

The drawing apparatus 100 (control unit 40) redundantly adds the correction regions CA1 to CA4 around the target drawing regions WA1 to WA4 to widen the stripe regions SA, and overscan a charged particle beam. The drawing apparatus 100 can perform drawing based on the drawing data corrected according to equation (3). When the thus-corrected drawing data is used, the control unit 40 controls each blanker of the blanker array 6 not to irradiate the outside of the shot region SH (outside the main-scan period) with a charged particle beam. To the contrary, the control unit 40 controls each blanker to perform drawing based on drawing data inside the shot region SH (within the main-scan period).

In this fashion, the drawing apparatus 100 corrects drawing data according to equation (3) for the respective target drawing regions WA1 to WA4, and performs drawing in regions including the correction regions CA1 to CA4. At this time, the correction regions CA1 to CA4 in the X direction are ensured by extending each stripe width SW, as described above. Thus, the deflection width (main-scan width) of a charged particle beam by the deflector array 8 needs to be increased. Increasing the deflection width is necessary to perform the aforementioned correction, but may prolong the time taken for drawing.

In a conventional exposure apparatus, even when distortions differ from each other in a plurality of shot regions SH formed on a substrate, the deflection width of a charged particle beam is set in advance to a predetermined value commonly used for all the shot regions SH. When the common deflection width is used for the plurality of shot regions SH, the deflection width of a charged particle beam may become redundant depending on the shot region SH, and the productivity (throughput) may drop. To prevent this, the drawing apparatus 100 according to the present invention determines the deflection width of a charged particle beam by adjusting, to minimum amounts necessary when actually correcting the shot region SH, the amounts of the correction regions CA1 to CA4 to be respectively added to the target drawing regions WA1 to WA4. A method of determining the deflection width of a charged particle beam will be explained below.

### First Embodiment

The first embodiment will explain a method of determining the deflection width of a charged particle beam with respect to each of arrays of shot regions (shot region array SL). A drawing apparatus 100 controls a deflector array 8 to deflect a charged particle beam in the X direction and perform drawing in each stripe region SA, while controlling a stage 11 to continuously move a substrate 10 in the Y direction. As a result, drawing in a plurality of shot regions SH formed on the substrate can be performed for each shot region array SL. The speed (moving speed (sub-scan speed) of the stage in the Y direction) at which a charged particle beam is scanned in the Y direction when performing drawing in each stripe region SA depends on the deflection width of the charged particle beam in the X direction. As the deflection width of a charged particle beam is smaller, the speed becomes higher. Since scanning of a charged particle beam in the Y direction is controlled by movement of the stage 11, as described above, the speed at which a charged particle beam is scanned in the Y direction may be common to the plurality of stripe regions SA. That is, the deflection width (stripe width SW) of a charged particle beam in the X direction may be commonly set for the plurality of stripe regions SA. The deflection width of a charged particle beam commonly set for the plurality of stripe regions SA can be changed for each shot region array SL based on information indicating the distortion of the shot region, and information indicating the displacement of the irradiation position of a charged particle beam.

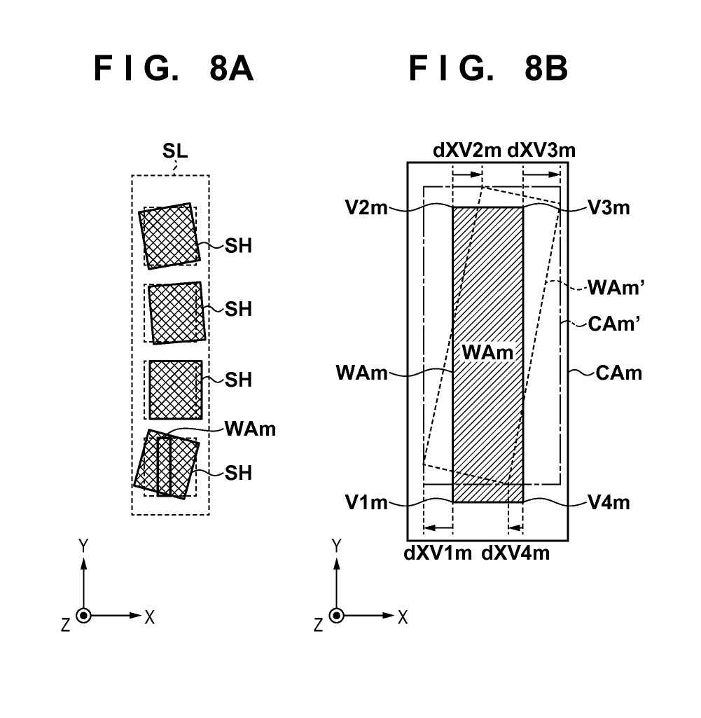

FIGS. 8A and 8B are views for explaining a method of determining the deflection width of a charged particle beam for each shot region array SL. A plurality of shot regions SH included in the shot region array SL have different shapes, as shown in FIG. 8A. The irradiation position of each charged particle beam is generated for each sub-array 5a (or objective lens OL). For this reason, the correction coefficients in equation (1) differ between the plurality of shot regions SH included in the shot region array SL, and the correction coefficients in equation (2) differ between the plurality of stripe regions SA. As a result, the correction amount (corrected drawing coordinates) represented by equation (3) differs between the target drawing regions WA1 to WA4 constituting each shot region SH, and the amount of a correction region necessary when correcting the shot region SH become different between them. The drawing apparatus 100 (a control unit 40) according to the first embodiment obtains the amounts (±X directions) of a correction region necessary for each of the target drawing regions WA1 to WA4 constituting each shot region SH included in the shot region array SL. The control unit 40 extends the stripe width SW by adding, to the width of the target drawing region, maximum values among the obtained amounts (±X directions) of the correction region. Based on the extended stripe width SW, the control unit 40 determines the deflection width of a charged particle beam in the shot region array SL.

For example, the control unit 40 obtains the amounts of a correction region necessary for each of the plurality of target drawing regions WA1 to WA4 constituting each of the plurality of shot regions SH included in the shot region array SL. A method of determining the amounts of a correction region necessary for a target drawing region WAm will be explained with reference to FIG. 8B. FIG. 8B is an enlarged view of a thick line portion in FIG. 8A. In FIG. 8B, the target drawing region WAm (an arbitrary numeral for discriminating each target drawing region is substituted into m) represents a target drawing region WA indicated by the thick line portion in FIG. 8A, and a broken line indicates a corrected target drawing region WAm′. In FIG. 8B, CAm is a correction region which has been estimated in advance and commonly set for all the shot regions SH, and CAm′ (chain line) is a correction region necessary for the target drawing region WAm.

Correction of the shape of the target drawing region WAm based on the correction amount of the shot region SH represented by equations (1) to (3) is conversion from a quadrangle into a quadrangle. The control unit 40 can therefore obtain the amount (X direction) of the necessary correction region CAm′ based on the correction amounts of four vertices Vim to V4m of the target drawing region WAm. The control unit 40 can obtain a correction amount (dXs+dXn) at the X-coordinate for the respective vertices Vim to V4m by transforming the coordinates of the four vertices Vim to V4m of the target drawing region WAm by using equations (1) and (2). Here, dXVim, dXV2m, dXV3m, and dXV4m are the correction amounts of the four vertices Vim to V4m, respectively. The control unit 40 selects a vertex positioned on the most −X direction side and a vertex positioned on the most X direction side, out of the four vertices Vim to V4m of the corrected target drawing region WAm′. In the example of FIG. 8B, the control unit 40 selects the vertex Vim as a vertex positioned on the most −X direction side, and the vertex V3m as a vertex positioned on the most X direction side. The control unit 40 sets the correction amount dXVim of the vertex Vim as the amount of the correction region CAm′ in the −X direction, and the correction amount dXV3m of the vertex V3m as the amount of the correction region CAm′ in the X direction. Hence, the control unit 40 can obtain the amounts (X direction and −X direction) of the correction region CAm′.

By the above-described method, the control unit 40 obtains the amounts (X direction and −X direction) of a correction region necessary for each of a plurality of target drawing regions constituting each of the plurality of shot regions SH included in the shot region array SL. The control unit 40 sets, as the stripe width SW, values obtained by adding, to the width of the target drawing region WA, maximum values among the obtained amounts (X direction and −X direction) of the correction region. Based on the set stripe width SW, the control unit 40 determines the deflection width of a charged particle beam in the shot region array SL. For example, assume that the amounts (X direction and −X direction) of the correction region CAm′ in the target drawing region WAm shown in FIG. 8B are maximum values. In this case, the control unit 40 sets, as the stripe width SW, values obtained by adding the correction amount dXVim of the vertex Vim to the width of the target drawing region WAm in the −X direction, and the correction amount dXV3m of the vertex V3m in the X direction. Based on the set stripe width SW, the control unit 40 determines the deflection width of a charged particle beam in the shot region array SL shown in FIG. 8A. The determined deflection width is commonly used in a plurality of shot regions SH included in the shot region array SL shown in FIG. 8A.

As described above, the speed (moving speed of the stage 11 in the Y direction) at which a charged particle beam is scanned in the Y direction when performing drawing in each stripe region SA depends on the deflection width of the charged particle beam in the X direction. Thus, the control unit 40 may determine the moving speed of the stage 11 for each shot region array SL in accordance with the deflection width of a charged particle beam that is determined for each shot region array SL. The moving speed of the stage 11 can be increased by the narrowing amount of the deflection width of a charged particle beam, and the productivity can be further increased. As one method of determining the moving speed of the stage 11, for example, the relation between the deflection width of a charged particle beam and the moving speed of the stage 11 is acquired in advance, and the moving speed of the stage 11 is determined from a deflection width determined based on the relation.

As described above, according to the first embodiment, the drawing apparatus 100 (control unit 40) controls the deflection width of a charged particle beam for each shot region array SL in accordance with the length (width), in the X direction, of each target drawing region WA to undergo drawing with each charged particle beam. The drawing apparatus 100 can narrow the deflection width of a charged particle beam and increase the productivity, compared to a conventional drawing apparatus in which the deflection width of a charged particle beam is set in advance to a predetermined value commonly used for all the shot regions SH. In the first embodiment, the amount of a correction region in the X direction for each target drawing region is obtained, and then the deflection width of a charged particle beam is obtained for each shot region array SL. However, it is also possible to directly obtain the deflection width of a charged particle beam for each shot region array SL from the correction amount of each vertex of each target drawing region.

### Second Embodiment

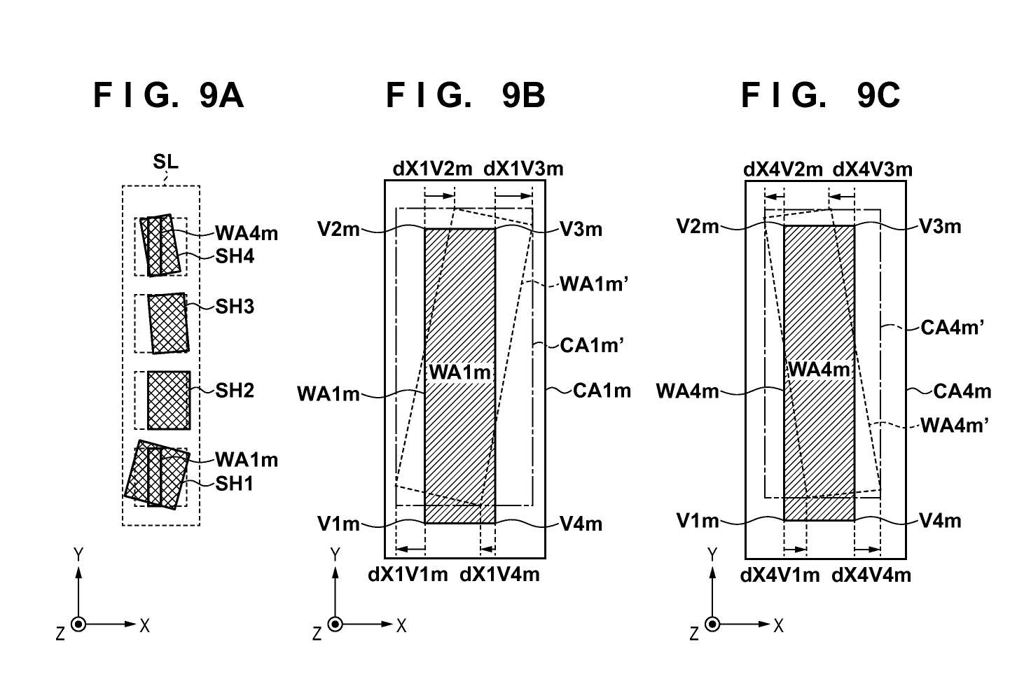

The second embodiment will explain a method of determining the deflection width of a charged particle beam for each shot region SH. FIGS. 9A to 9C are views for explaining a method of determining the deflection width of a charged particle beam for each shot region SH. The plurality of shot regions SH included in a shot region array SL are different not only in the rotation component, but also in the magnification component in the X direction, as shown in FIG. 9A. In FIG. 9A, the respective shot regions SH will be referred to as shot regions SH1 to SH4 in order from the bottom on the paper surface. Assume that the magnification component decreases in order from the shot region SH1 to the shot region SH4.

FIG. 9B is an enlarged view of a thick line portion in the shot region SH1 in FIG. 9A. FIG. 9C is an enlarged view of a thick line portion in the shot region SH4 in FIG. 9A. In FIG. 9B, a target drawing region WA1m (an arbitrary numeral for discriminating each target drawing region is substituted into m) represents a target drawing region WA indicated by the thick line portion in the shot region SH1 in FIG. 9A, and a broken line indicates a corrected target drawing region WA1m′. In FIG. 9B, CA1m is a correction region which has been estimated in advance and commonly set for all the shot regions SH, and CA1m′ (chain line) is a correction region necessary for the target drawing region WA1m. Similarly, in FIG. 9C, a target drawing region WA4m (an arbitrary numeral for discriminating each target drawing region is substituted into m) represents a target drawing region WA indicated by the thick line in the shot region SH4 in FIG. 9A, and a broken line indicates a corrected target drawing region WA4m′. In FIG. 9C, CA4m is a correction region which has been estimated in advance and commonly set for all the shot regions SH, and CA4m′ (chain line) is a correction region necessary for the target drawing region WA4m.

By using the method of determining the amounts (±X directions) of a correction region, which has been described in the first embodiment, a control unit 40 determines, for each shot region SH, a deflection width by which a deflector array 8 deflects a charged particle beam. For example, assume that the amounts (X direction and −X direction) of the correction region CA1m′ in the target drawing region WA1m shown in FIG. 9B are maximum values among a plurality of target drawing regions WA included in the shot region SH1. In this case, the control unit 40 sets, as a stripe width SW, values obtained by adding a correction amount dX1V1m of a vertex Vim to the width of the target drawing region WA1m in the −X direction, and a correction amount dX1V3m of a vertex V3m in the X direction. Based on the set stripe width SW, the control unit 40 determines a deflection width in the shot region SH1. By determining the deflection width in this way, the amounts (±X directions) of the correction region CA1m′ can become smaller than the amounts (±X directions) of the correction region CA1m that have been estimated in advance. The deflection width of a charged particle beam by the deflector array 8 can be narrowed. Since the moving speed (sub-scan speed) of a stage 11 in the Y direction can be increased by the narrowing amount of the deflection width, the time taken for drawing on a substrate 10 can be shortened, and the productivity can be increased.

Similarly, for example, assume that the amounts (X direction and −X direction) of the correction region CA4m′ in the target drawing region WA4m shown in FIG. 9C are maximum values among the plurality of target drawing regions WA included in the shot region SH4. In this case, the control unit 40 sets, as the stripe width SW, values obtained by adding a correction amount dX4V2m of a vertex V2m to the width of the target drawing region WA4m in the −X direction, and a correction amount dX4V4m of a vertex V4m in the X direction. Based on the set stripe width SW, the control unit 40 determines a deflection width in the shot region SH4. By determining the deflection width in this way, the amounts (±X directions) of the correction region CA4m′ can become smaller than the amounts (±X directions) of the correction region CA4m that have been estimated in advance. The deflection width of a charged particle beam by the deflector array 8 can be narrowed. Since the moving speed of the stage 11 in the Y direction can be increased by the narrowing amount of the deflection width, the time taken for drawing on the substrate 10 can be shortened, and the productivity can be increased.

For example, the amounts (±X directions) of the correction region CA4m′ shown in FIG. 9C are smaller than the amounts (±X directions) of the correction region CA1m′ shown in FIG. 9B. In this case, a deflection width at the time of drawing in the shot region SH4 can become narrower than a deflection width at the time of drawing in the shot region SH1. Hence, the time taken for drawing can become shorter in the shot region SH4 than in the shot region SH1. That is, when the widths of the correction regions CA1m′ to CA4m′ in the X direction for the plurality of shot regions SH1 to SH4 are different from each other, it suffices to determine the deflection width for each shot region SH. By determining the deflection width for each shot region SH, the time taken for drawing on the substrate 10 can be shortened, compared to a case in which the deflection width is determined for each shot region array SL.

As described above, according to the second embodiment, a drawing apparatus 100 (the control unit 40) controls the deflection width of a charged particle beam for each shot region SH in accordance with the length, in the X direction, of the target drawing region WA to undergo drawing with each charged particle beam. The drawing apparatus 100 can narrow the deflection width of a charged particle beam and increase the productivity, compared to a conventional drawing apparatus in which the deflection width of a charged particle beam is set in advance to a predetermined value commonly used for all the shot regions SH. The control unit 40 may determine the moving speed of the stage 11 for each shot region SH in accordance with the deflection width of a charged particle beam determined for each shot region SH. The moving speed of the stage 11 can be increased by the narrowing amount of the deflection width of a charged particle beam, and the productivity can be further increased.

The first and second embodiments have been described using an example in which the shot region SH is divided by each stripe region SA into the target drawing regions WA, and the respective target drawing regions WA are corrected. However, the present invention is not limited to this. By more finely dividing the shot region SH and performing correction regardless of the division direction, the present invention can cope with even correction of a higher-order nonlinear shape. For example, in a plurality of more finely divided target drawing regions WA, a common deflection width is obtained by the above-described method for each shot region SH, each shot region array, or another unit. The above-described embodiments have explained a method of correcting a quadrangle into a quadrangle. However, even when correcting a quadrangle into an arbitrary figure, the deflection width can be obtained from coordinates on the outer periphery of the quadrangle by the above-described method.

<Embodiment of Method of Manufacturing Article>

A method of manufacturing an article according to an embodiment of the present invention is suitable for manufacturing an article such as a microdevice (for example, a semiconductor device) or an element having a microstructure. The method of manufacturing an article according to the embodiment includes a step of forming a latent image pattern on a photosensitive agent applied to a substrate by using the above-described drawing apparatus (a step of performing drawing on a substrate), and a step of developing the substrate on which the latent image pattern has been formed in the preceding step. Further, this manufacturing method includes other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-233454 filed on Nov. 11, 2013, which is hereby incorporated by reference herein in its entirety.

What is claimed is:

1. A drawing apparatus which performs drawing on a substrate with a charged particle beam, the apparatus comprising:
a deflector configured to scan the charged particle beam on the substrate;
a stage configured to hold the substrate and be movable; and
a controller configured to control main-scan by the deflector and sub-scan by movement of the stage,
wherein the controller is configured to control a width of the main-scan based on a width of a target drawing region on the substrate in a direction of the main-scan.

2. The apparatus according to claim 1, further comprising a blanker configured to blank the charged particle beam,
wherein the controller is configured to control the blanker so as to blank the charged particle beam outside a period of the main-scan, and blank the charged particle beam based on drawing data within the period of the main-scan.

3. The apparatus according to claim 1, wherein the controller is configured to determine the width of the main-scan with respect to each shot region based on information regarding a size of each shot region on the substrate in the direction of the main-scan.

4. The apparatus according to claim 3, wherein the controller is configured to control a speed of the sub-scan with respect to each shot region based on the width of the main-scan determined with respect to each shot region.

5. The apparatus according to claim 1, wherein the controller is configured to determine the width of the main-scan with respect to each of arrays of shot regions along a direction of the sub-scan based on information regarding a size of each shot region on the substrate in the direction of the main-scan.

6. The apparatus according to claim 5, wherein the controller is configured to control a speed of the sub-scan with respect to each of the arrays based on the width of the main-scan determined with respect to each of the arrays.

7. The apparatus according to claim 3, further comprising a measurement device configured to obtain the information regarding the size.

8. The apparatus according to claim 7, wherein the measurement device is configured to measure a position of a mark formed with respect to each shot region.

9. The apparatus according to claim 1, wherein the controller is configured to determine the width of the main-scan further based on information indicating a displacement of a position of the charged particle beam on the substrate from a target position.

10. The apparatus according to claim 1, wherein
the drawing apparatus is configured to perform drawing with a plurality of charged particle beams arrayed in the direction of the main-scan, and obtain the target drawing region with respect to each of the plurality of charged particle beams.

11. The apparatus according to claim 10, wherein the controller is configured to set the same width of the main-scan with respect to the plurality of charged particle beams based on widths of a plurality of the target drawing region respectively corresponding to the plurality of charged particle beams.

12. A method of manufacturing an article, the method comprising steps of:
performing drawing on a substrate using a drawing apparatus;
developing the substrate on which the drawing has been performed; and
processing the developed substrate to manufacture the article,
wherein the drawing apparatus performs drawing on the substrate with a charged particle beam, and includes:
a deflector configured to scan the charged particle beam on the substrate;
a stage configured to hold the substrate and be movable; and
a controller configured to control main-scan by the deflector and sub-scan by movement of the stage,
wherein the controller is configured to control a width of the main-scan based on a width of a target drawing region on the substrate in a direction of the main-scan.
